(19) United States
(12) Patent Application Publication
(10) Pub. No.: US 2026/0119742 A1
(43) Pub. Date: Apr. 30, 2026

(54) INFORMATION PROCESSING METHOD, INFORMATION PROCESSING SYSTEM, AND NON-TRANSITORY COMPUTER-READABLE RECORDING MEDIUM

(71) Applicant: Panasonic Intellectual Property Management Co., Ltd., Osaka (JP)

(72) Inventors: KAZUHIDE ICHIKAWA, Kyoto (JP); SATORU OHUCHI, Hyogo (JP); TOMOYASU YOKOYAMA, Osaka (JP); KOKI UENO, Osaka (JP)

(21) Appl. No.: 19/415,986

(22) Filed: Dec. 11, 2025

Related U.S. Application Data
(63) Continuation of application No. PCT/JP2024/022285, filed on Jun. 19, 2024.

(30) Foreign Application Priority Data
Jun. 27, 2023 (JP) 2023-105228

(51) Int. Cl. G06F 30/20

(52) U.S. Cl. CPC G06F 30/20

(57) ABSTRACT

An information processing method is executed by a computer and includes: acquiring interfacial model information indicating an interfacial model of two or more solid materials; executing a simulation of a reaction between the two or more solid materials based on the acquired interfacial model information; and outputting progress information indicating a degree of progress of the reaction based on reaction information related to the reaction obtained by the simulation.

### BACKGROUND

### 1. Technical Field

The present disclosure relates to, for example, techniques for estimating reactions between two or more solid materials.

### 2. Description of the Related Art

According to Tao Cheng, Boris V. Merinov, Sergey Morozov, and William A. Goddard, III, ACS Energy Lett. 2017, 2, 1454-1459, “Quantum Mechanics Reactive Dynamics Study of Solid Li-Electrode/Li₆PS₅Cl-Electrolyte Interface” (referred to as “Non Patent Literature 1” hereinafter), a technique disclosed involves performing a molecular dynamics (MD) calculation on an interfacial model between lithium (Li) metal and a solid electrolyte to determine the interfacial reactivity and decomposition products.

Japanese Unexamined Patent Application Publication No. 2022-62524 (referred to as “Patent Literature 1” hereinafter) discloses a technique involving performing an MD calculation on an interfacial model of metallic materials, performing structural relaxation, and calculating the interfacial energy.

### SUMMARY

One non-limiting and exemplary embodiment provides, for example, an information processing method that facilitates an estimation of the degree of reaction progress between two or more solid materials.

In one general aspect, the techniques disclosed here feature an information processing method executed by a computer and including: acquiring interfacial model information indicating an interfacial model of two or more solid materials; executing a simulation of a reaction between the two or more solid materials based on the acquired interfacial model information; and outputting progress information indicating a degree of progress of the reaction based on reaction information related to the reaction obtained by the simulation.

The present disclosure facilitates an estimation of the degree of reaction progress between two or more solid materials.

This general or specific aspect may be achieved in accordance with a device, a system, an integrated circuit, a computer program, or a computer readable recording medium, or may be achieved in accordance with an arbitrary combination of a method, a device, a system, an integrated circuit, a computer program, and a recording medium. The computer readable recording medium may include a nonvolatile recording medium, such as a compact disc-read only memory (CD-ROM).

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a block diagram illustrating the overall configuration including an information processing system according to an embodiment;

FIG. 2 schematically illustrates an example of operation performed by the information processing system according to the embodiment;

FIG. 3 schematically illustrates a calculation example of the degree of reaction progress;

FIG. 4 illustrates an example of the radial distribution function of lithium metal;

FIG. 5 illustrates an example of the radial distribution function of an iodine crystal;

FIG. 6 illustrates an example of the radial distribution function of a lithium iodide crystal;

FIG. 7 schematically illustrates an example where a reaction end time is calculated by using the radial distribution function;

FIG. 8 schematically illustrates an example where the reaction end time is calculated by using the radial distribution function;

FIG. 9 schematically illustrates an example where the reaction end time is calculated by using the radial distribution function;

FIG. 10 schematically illustrates an example where the volume of a reaction product is calculated by using the coordination number;

FIG. 11 is a flowchart illustrating an operation example of the information processing system according to the embodiment;

FIG. 12 is a flowchart illustrating an example of operation performed by the information processing system according to the embodiment for calculating the reaction end time;

FIG. 13 is a flowchart illustrating an example of operation performed by the information processing system according to the embodiment for calculating the volume of the reaction product;

FIG. 14 illustrates an example of a first image and a second image displayed on a display in the embodiment;

FIG. 15 illustrates another example of the second image displayed on the display in the embodiment;

FIG. 16 illustrates an example of the first image and a third image displayed on the display in the embodiment;

FIG. 17 illustrates an example of a fourth image displayed on the display in the embodiment;

FIG. 18 illustrates an example of a fifth image displayed on the display in the embodiment;

FIG. 19 schematically illustrates an example where the reaction end time is calculated by using smooth overlap of atomic positions (SOAP) descriptors;

FIG. 20 schematically illustrates an example where the reaction end time is calculated by using SOAP descriptors;

FIG. 21 is a diagram for explaining a reaction occurrence region in an interfacial model;

FIG. 22 schematically illustrates an example where the volume of a reaction product is calculated by using a histogram;

FIG. 23 illustrates an example of the interfacial model;

FIG. 24 illustrates another example of the interfacial model; and

FIG. 25 illustrates yet another example of the interfacial model.

### DETAILED DESCRIPTIONS

Underlying Knowledge Forming Basis of the Present Disclosure With regard to calculations in materials development in recent years, the reaction rate of a reaction between molecules and the reaction rate of a reaction between a solid surface and a molecule (e.g., catalytic reaction) are predicted relatively easily and relatively accurately by using a theory or tool, such as the transition state theory or global reaction route mapping (GRRM). On the other hand, there is a lack of calculation methods for the reaction rate of a reaction between solid materials (e.g., sintering reaction).

Therefore, even if a material with a certain composition is predicted to exhibit favorable properties, when there is an attempt to synthesize the material by mixing solid materials included in the composition and causing the solid materials to react with each other, there is no solution for predicting how long the reaction should take or whether the synthesis is practically possible due to requiring an excessive amount of time for the synthesis of the material. Therefore, at present, much experimental trial and error is still required.

Non Patent Literature 1 discloses a technique involving performing a molecular dynamics (MD) calculation on an interfacial model between lithium (Li) metal and a solid electrolyte to determine the interfacial reactivity and decomposition products. In detail, Non Patent Literature 1 involves creating an interfacial model by using lithium metal and a solid electrolyte Li₆PS₅Cl, performing a first principle MD calculation on the interfacial model, and simulating a chemical reaction occurring at the interface. This interfacial model is obtained by cutting each of a lithium-metal crystal structure and a solid electrolyte Li₆PS₅Cl crystal structure, along a certain crystallographic plane and joining the cut surfaces together.

In Non Patent Literature 1, in order to indicate that LiCl crystals are produced as a result of the chemical reaction at the interface, the radial distribution function (RDF), which is one characteristic of the structure of the interfacial model, is compared before and after the MD calculation. In this comparison, an RDF peak, which is characteristic of LiCl crystals and not existent before the MD calculation, emerges after the MD calculation. Thus, with the technique according to Non Patent Literature 1, it is possible to indicate that LiCl crystals are produced as a result of the chemical reaction. However, since it is not possible to determine the amount of LiCl crystals produced, that is, the amount of reaction products, with the technique according to Non Patent Literature 1, it is not possible to calculate the reaction rate.

Patent Literature 1 discloses a technique involving performing an MD calculation on an interfacial model of metallic materials, performing structural relaxation, and calculating the interfacial energy. In the technique according to Patent Literature 1, the MD calculation is used for the purpose of predicting a stable interfacial structure and calculating the interfacial energy from an energy difference between the interfacial structure and the structure of the original material, but is not based on an assumption that a chemical reaction occurs at the interface. Therefore, it is not possible to calculate the reaction rate.

In order to solve the aforementioned problems, an information processing method according to a first aspect of the present disclosure is an information processing method executed by a computer and includes: acquiring interfacial model information indicating an interfacial model of two or more solid materials; executing a simulation of a reaction between the two or more solid materials based on the acquired interfacial model information; and outputting progress information indicating a degree of progress of the reaction based on reaction information related to the reaction obtained by the simulation.

This is advantageous in that the degree of reaction progress can be readily estimated instead of simply estimating a reaction product of the two or more solid materials. The degree of reaction progress can be ascertained without having to actually synthesize the two or more solid materials. Specifically, the user can determine whether experimental verification is necessary and plan experimental conditions in accordance with the degree of reaction progress, thus contributing to the efficiency of materials development.

Furthermore, for example, according to the information processing method according to a second aspect of the present disclosure, in the first aspect, the outputting the progress information may include outputting the progress information including characteristic information indicating a characteristic of a structure generated by the reaction.

This is advantageous in that a characteristic of the structure generated by the reaction between the two or more solid materials can be readily estimated. Moreover, this is also advantageous in that, by performing a conversion to an amount indicating the characteristic of the structure and outputting the amount, threshold values, such as the time at which the chemical reaction starts and the time at which the chemical reaction ends, can be readily quantified.

Furthermore, for example, according to the information processing method according to a third aspect of the present disclosure, in the first or second aspect, the two or more solid materials may include a first solid material and a second solid material. The acquiring the interfacial model information may include: acquiring first structural model information, which indicates a first structural model of a structure of the first solid material, and second structural model information, which indicates a second structural model of a structure of the second solid material; and generating the interfacial model obtained by combining the first structural model and the second structural model based on the acquired first structural model information and the acquired second structural model information.

This is advantageous in that the degree of reaction progress between the first solid material and the second solid material can be readily estimated. The degree of reaction progress can be ascertained without having to actually synthesize the first solid material and the second solid material. Specifically, the user can determine whether experimental verification is necessary and plan experimental conditions in accordance with the degree of reaction progress, thus contributing to the efficiency of materials development.

Furthermore, for example, according to the information processing method according to a fourth aspect of the present disclosure, in the first or second aspect, the simulation may be a molecular dynamics simulation, and the reaction information may include first data indicating the interfacial model corresponding to a start time of the simulation and second data indicating the interfacial model corresponding to an end time of the simulation.

This is advantageous in that the degree of reaction progress between the two or more solid materials can be readily estimated. The degree of reaction progress can be ascertained without having to actually synthesize the two or more solid materials. Specifically, the user can determine whether experimental verification is necessary and plan experimental conditions in accordance with the degree of reaction progress, thus contributing to the efficiency of materials development.

Furthermore, for example, according to the information processing method according to a fifth aspect of the present disclosure, in the fourth aspect, the outputting the progress information may include: outputting the progress information including information indicating that the reaction has occurred when the interfacial model indicated by the second data includes a reaction occurrence region including a mixture of atoms respectively contained in the two or more solid materials; and outputting the progress information including information indicating that the reaction has not occurred when the interfacial model indicated by the second data does not include the reaction occurrence region.

This is advantageous in that the degree of reaction progress between the two or more solid materials can be readily estimated. The degree of reaction progress can be ascertained without having to actually synthesize the two or more solid materials. Specifically, the user can determine whether experimental verification is necessary and plan experimental conditions in accordance with the degree of reaction progress, thus contributing to the efficiency of materials development.

Furthermore, for example, according to the information processing method according to a sixth aspect of the present disclosure, in the fourth or fifth aspect, the outputting the progress information may include calculating a rate of the reaction based on a difference between the start time and the end time and outputting the progress information including the calculated rate of the reaction.

This is advantageous in that the reaction rate of the two or more solid materials can be readily estimated. The reaction rate can be ascertained without having to actually synthesize the two or more solid materials. Specifically, the user can determine whether experimental verification is necessary and plan experimental conditions in accordance with the reaction rate, thus contributing to the efficiency of materials development.

Furthermore, for example, according to the information processing method according to a seventh aspect of the present disclosure, in any one of the first to sixth aspects, the simulation may be a molecular dynamics simulation, and the outputting the progress information may include outputting a radial distribution function of at least one atom included in the interfacial model during execution of the simulation. The radial distribution function serves as characteristic information that is included in the progress information and that indicates a characteristic of a structure generated by the reaction.

This is advantageous in that the degree of reaction progress between the two or more solid materials can be readily estimated. The degree of reaction progress can be ascertained without having to actually synthesize the two or more solid materials. Specifically, the user can determine whether experimental verification is necessary and plan experimental conditions in accordance with the degree of reaction progress, thus contributing to the efficiency of materials development.

Furthermore, for example, according to the information processing method according to an eighth aspect of the present disclosure, in the seventh aspect, the outputting the progress information may include estimating that a time at which a predetermined peak included in the radial distribution function at a start time of the simulation disappears is an end time of the reaction, and outputting the progress information including the estimated end time of the reaction.

This is advantageous in that the end time of the reaction between the two or more solid materials can be readily estimated. Moreover, this is also advantageous in that the reaction rate can be readily quantified.

Furthermore, for example, according to the information processing method according to a ninth aspect of the present disclosure, in the seventh or eighth aspect, the outputting the progress information may include calculating a volume of a reaction product, produced by the reaction, based on a coordination number of an atom included in the interfacial model with respect to a predetermined crystal axis, and outputting the progress information including the calculated volume of the reaction product.

This is advantageous in that the volume of the reaction product produced by the reaction between the two or more solid materials can be readily estimated. Moreover, this is also advantageous in that the reaction rate can be readily quantified.

Furthermore, for example, according to the information processing method according to a tenth aspect of the present disclosure, in the ninth aspect, the outputting the progress information may include: calculating a reaction time, indicating a time from when the reaction starts to when the reaction ends, based on a difference between the start time and the end time; and calculating a rate of the reaction based on the calculated reaction time and the calculated volume of the reaction product and outputting the progress information including the calculated rate of the reaction.

This is advantageous in that the reaction rate of the two or more solid materials can be readily estimated. The reaction rate can be ascertained without having to actually synthesize the two or more solid materials. Specifically, the user can determine whether experimental verification is necessary and plan experimental conditions in accordance with the reaction rate, thus contributing to the efficiency of materials development. Furthermore, for example, according to the information processing method according to an eleventh aspect of the present disclosure, in any one of the first to tenth aspects, the executing the simulation may include: executing a structural relaxation calculation on the interfacial model based on the acquired interfacial model information; and executing the simulation on the interfacial model after the structural relaxation calculation.

Accordingly, for example, even when it is difficult to execute the simulation due to an excessively large gap between the solid materials in the interfacial model, it is possible to facilitate the simulation by reducing the gap between the solid materials. Since the structural relaxation calculation normally enables a faster calculation for reducing such a gap than the molecular dynamics calculation, the simulation time can be readily shortened. With the shortened simulation time, the computer that executes the information processing method can save computing resources.

An information processing system according to a twelfth aspect of the present disclosure includes a display controller that causes a display to display a second image after a first image is displayed on the display. The first image receives an input of first solid material information indicating a first solid material and an input of second solid material information indicating a second solid material. The second image indicates progress information that indicates a degree of progress of a reaction between the first solid material and the second solid material and that is generated based on the first solid material information and the second solid material information that are input.

Accordingly, the user can ascertain the degree of reaction progress between the first solid material and the second solid material by viewing the second image. The degree of reaction progress can be ascertained without having to actually synthesize the first solid material and the second solid material. Specifically, the user can determine whether experimental verification is necessary and plan experimental conditions in accordance with the degree of reaction progress, thus contributing to the efficiency of materials development.

Furthermore, for example, according to the information processing system according to a thirteenth aspect of the present disclosure, in the twelfth aspect, the display controller may cause the display to further display a third image indicating first interfacial model information generated based on the first solid material information and the second solid material information that are input, and the first interfacial model information may indicate a first interfacial model generated as a result of the first solid material and the second solid material coming into contact with each other. The first solid material has a first structure including first atoms. The second solid material has a second structure including second atoms. The first interfacial model includes a boundary region between the first structure and the second structure.

Accordingly, by viewing the third image, the user can ascertain what kind of an interfacial model is used for simulating a reaction. This enables visual recognition of not only material composition information but also structural information, thereby facilitating checking of whether an assumed reaction can be simulated.

Furthermore, for example, according to the information processing system according to a fourteenth aspect of the present disclosure, in the thirteenth aspect, the display controller may cause the display to further display a fourth image and a fifth image. The fourth image receives an input of calculation method information indicating a calculation method executable on the first interfacial model. The fifth image indicates second interfacial model information generated based on the calculation method information that is input.

The display controller causes the display to further display the fourth image that receives the input of the calculation method information indicating the calculation method executable on the first interfacial model. Accordingly, by viewing the fourth image, the user can select a desired calculation method to be executed on the interfacial model. By presenting options in advance, users unfamiliar with calculation methods can appropriately select a calculation method to a certain extent, thereby facilitating the simulation of a chemical reaction.

The display controller further causes the display to further display the fifth image indicating the second interfacial model information generated based on the input calculation method information.

Accordingly, by viewing the fifth image, the user can ascertain the interfacial model obtained after the simulation. Making the interfacial model obtained after the simulation visible facilitates checking of whether a chemical reaction has occurred and allows the user to determine whether experimental verification is necessary and plan experimental conditions, thus contributing to the efficiency of materials development. A program according to a fifteenth aspect of the present disclosure causes a computer to execute a process including: acquiring interfacial model information indicating an interfacial model of two or more solid materials; executing a simulation of a reaction between the two or more solid materials based on the acquired interfacial model information; and outputting progress information indicating a degree of progress of the reaction based on reaction information related to the reaction obtained by the simulation. The two or more solid materials each include atoms.

This is advantageous in that the degree of reaction progress can be readily estimated instead of simply estimating a reaction product of the two or more solid materials. The degree of reaction progress can be ascertained without having to actually synthesize the two or more solid materials. Specifically, the user can determine whether experimental verification is necessary and plan experimental conditions in accordance with the degree of reaction progress, thus contributing to the efficiency of materials development.

The characteristic process included in the information processing method according to the present disclosure may be implemented as a computer program executed by a computer. Needless to say, such a computer program may be distributed via a non-transitory computer-readable recording medium, such as a CD-ROM, or via a communication network, such as the Internet.

Embodiments will be described in detail below with reference to the drawings.

The embodiments to be described below indicate general or specific examples of the present disclosure. Numerical values, shapes, materials, components, positions and connection methods of the components, steps, the order of the steps, and so on indicated in the embodiments below are examples, and are not intended to limit the present disclosure. Among the components in the embodiments below, a component not defined in an independent claim indicating the most generic concept is described as an arbitrary component. Furthermore, the drawings are schematic and are not necessarily exact illustrations. In each drawing, same reference signs are given to identical components.

An information processing system according to an embodiment of the present disclosure may be configured such that all components are included in a single computer, or may be configured such that multiple components are respectively distributed to multiple computers.

### EMBODIMENT

The information processing system (or an information processing method or a program) according to the embodiment of the present disclosure will be described below with reference to the drawings.

### Information Processing System

The configuration of the information processing system used in the embodiment will be described first.

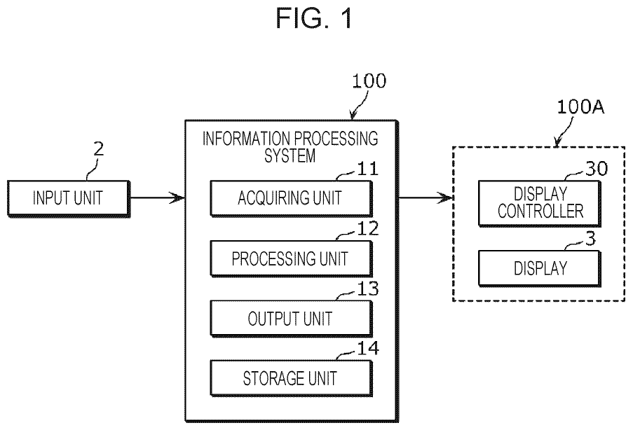

FIG. 1 is a block diagram illustrating the overall configuration including an information processing system 100 according to the embodiment. The information processing system 100 is configured as a computer, such as a personal computer or a server. Specifically, the information processing system 100 may be implemented by, for example, cloud computing. In the embodiment, the information processing system 100 is described as being a stationary computer.

The information processing system 100 includes an acquiring unit 11, a processing unit 12, an output unit 13, and a storage unit 14. The information processing system 100 is connected to an input unit 2, a display controller 30, and a display 3. The input unit 2, the display controller 30, and the display 3 are included in an information terminal used by a user, such as a smartphone, a tablet terminal, or a personal computer.

The input unit 2 and the display controller 30 may both be connected to the information processing system 100 by, for example, a local area network (LAN), or may be connected to the information processing system 100 via a network such as the Internet.

The input unit 2 is an input interface that receives an input from the user and is constituted of, for example, a keyboard, a touch sensor, a touch pad, or a mouse. The input unit 2 receives an input operation by the user and outputs a signal according to the input operation to the information processing system 100. In the present disclosure, the display 3 and the input unit 2 are independent of each other, but may alternatively be integrated with each other, as in a touchscreen. In the present disclosure, the information processing system 100 does not include the display 3 and the input unit 2, but may alternatively include these units.

The input unit 2 receives an input of solid material information indicating each of two or more solid materials desired by the user. In the embodiment, the input unit 2 receives an input of first solid material information indicating a first solid material and an input of second solid material information indicating a second solid material. Naturally, the input unit 2 may receive an input of solid material information indicating each of three or more solid materials. Each piece of information received by the input unit 2 indicates the material name (including the compound name) of the solid material, the composition formula indicating the composition of the solid material, the crystal structure of the solid material, or the like.

The display controller 30 causes the display 3 to display an image or the like based on information output from the output unit 13 of the information processing system 100.

The display 3 displays an image or the like by being controlled by the display controller 30. The display 3 is, for example, a liquid crystal display, a plasma display, or an organic electro-luminescence (EL) display, but is not limited thereto.

The acquiring unit 11 acquires interfacial model information indicating an interfacial model of the two or more solid materials. The acquiring unit 11 is responsible for executing a step for acquiring the interfacial model information in the information processing method according to the present disclosure. In the embodiment, based on the first solid material information received by the input unit 2, the acquiring unit 11 acquires first structural model information indicating a first structural model of the structure of the first solid material. Moreover, based on the second solid material information received by the input unit 2, the acquiring unit 11 acquires second structural model information indicating a second structural model of the structure of the second solid material.

When the crystal structures of the first solid material and the second solid material are input to the input unit 2, the acquiring unit 11 acquires first structural model information in which the input crystal structure of the first solid material is set as the first structural model, and acquires second structural model information in which the input crystal structure of the second solid material is set as the second structural model. On the other hand, if crystal structures of the first solid material and the second solid material are not input to the input unit 2, the acquiring unit 11 may acquire a first structural model and a second structural model respectively corresponding to the material names (or the composition formulas) of the first solid material and the second solid material from, for example, an external database, so as to acquire first structural model information and second structural model information. Alternatively, the acquiring unit 11 may input the material names (or the composition formulas) of the first solid material and the second solid material into, for example, a prediction system capable of predicting structural models, so as to acquire a first structural model and a second structural model predicted by the prediction system, thereby acquiring first structural model information and second structural model information.

Then, based on the acquired first structural model information and second structural model information, the acquiring unit 11 generates an interfacial model having a combination of the first structural model and the second structural model, thereby acquiring the interfacial model. In detail, the acquiring unit 11 uses material analysis software to superimpose any crystal plane of the first structural model and any crystal plane of the second structural model, thereby generating the interfacial model. In the process for generating the interfacial model, each crystal plane to be used may be determined by specifying, for example, the Miller indices, or may be a default crystal plane. Furthermore, in the process for generating the interfacial model, a certain degree of strain may be permitted, and the degree to which the strain is permitted may be appropriately set by the user.

The processing unit 12 executes a simulation of a reaction between the two or more solid materials based on the interfacial model information acquired by the acquiring unit 11. The processing unit 12 is responsible for executing a step for executing a simulation in the information processing method according to the present disclosure. In the embodiment, based on the interfacial model information acquired by the acquiring unit 11, the processing unit 12 executes a structural relaxation calculation on the interfacial model and executes a simulation on the structurally-relaxed interfacial model.

The structural relaxation calculation involves optimizing the lattice constant of the interfacial model as well as the coordinates (position) of each atom in the interfacial model. In detail, the structural relaxation calculation involves calculating a force acting on each atom in the interfacial model based on a first principle calculation, and optimizing the coordinates of the atom so that the force acting on the atom becomes zero or less than or equal to a threshold value. When the structural relaxation calculation is executed on the interfacial model, for example, even if it is difficult to execute the simulation due to an excessively large gap between the solid materials in the interfacial model, it is possible to facilitate the simulation by reducing the gap between the solid materials. Whether or not the structural relaxation calculation is to be executed can be appropriately set by the user. If the structural relaxation calculation is not to be executed, the processing unit 12 executes the simulation on the interfacial model acquired by the acquiring unit 11.

In the embodiment, the processing unit 12 executes the simulation by executing a molecular dynamics (MD) calculation on the structurally-relaxed interfacial model. In other words, the simulation executed by the processing unit 12 is based on molecular dynamics. The process executed by the processing unit 12 will be described in detail later.

The output unit 13 outputs an image or the like to the display controller 30 so as to cause the display 3 to display the image or the like. Moreover, the output unit 13 outputs progress information indicating the degree of reaction progress based on reaction information related to reaction obtained in accordance with the simulation executed by the processing unit 12. The output unit 13 is responsible for executing a step for outputting progress information in the information processing method according to the present disclosure. In detail, the output unit 13 causes the display 3 to display an image indicating the progress information generated by the processing unit 12, so as to output the progress information. The process executed by the output unit 13 will be described in detail later.

The progress information may include, for example, information indicating whether a reaction between the two or more solid materials has occurred. Moreover, for example, if a reaction between the two or more solid materials has occurred, the progress information may include information indicating the time required for the reaction (i.e., reaction time) or the reaction rate. Furthermore, for example, if a reaction between the two or more solid materials has occurred, the progress information may include characteristic information indicating a characteristic of a structure generated as a result of the reaction.

Characteristic information may include, for example, a coordination environment, such as the radial distribution function (RDF), bond order parameter, or coordination number. Furthermore, the characteristic information may include, for example, a smooth overlap of atomic positions (SOAP) descriptor. The embodiment described here relates to an example where the radial distribution function (RDF) and the coordination number are used as the characteristic information. An example where a SOAP descriptor is used as the characteristic information will be described in the modifications.

The storage unit 14 is a recording medium for storing data (including a program) to be used in various processes executable by the information processing system 100. Examples of the recording medium include a hard disk drive, a random access memory (RAM), a read only memory (ROM), and a semiconductor memory. Such a recording medium may be volatile or nonvolatile.

### Process

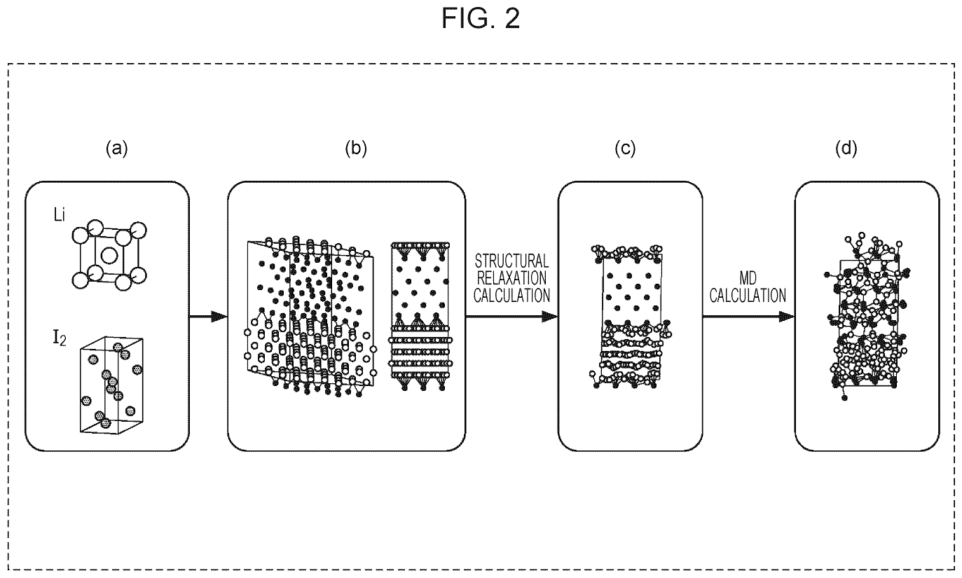

Next, an example of a process executed by the information processing system 100 according to the embodiment will be described with reference to the drawings. FIG. 2 schematically illustrates an example of operation performed by the information processing system 100 according to the embodiment. As illustrated in FIG. 2(a), the input unit 2 receives an input of solid material information indicating each of the two or more solid materials. In the example illustrated in FIG. 2(a), the input unit 2 receives information (e.g., Caltech Intermediate Form (CIF) file) indicating a lithium metal structure as first solid material information and information (e.g., CIF file) indicating an iodine crystal structure as second solid material information.

Then, as illustrated in FIG. 2(b), the acquiring unit 11 of the information processing system 100 generates an interfacial model based on the solid material information received by the input unit 2, thereby acquiring the interfacial model. In the example illustrated in FIG. 2(b), the interfacial model generated by the acquiring unit 11 is constituted of 120 lithium atoms and 72 iodine atoms. Subsequently, as illustrated in FIG. 2(c), based on the interfacial model information acquired by the acquiring unit 11, the processing unit 12 of the information processing system 100 executes a structural relaxation calculation, thereby acquiring a structurally-relaxed interfacial model. In the structural relaxation calculation, the lattice constant may be variable.

Then, as illustrated in FIG. 2(d), the processing unit 12 of the information processing system 100 executes an MD calculation (i.e., molecular-dynamics-based simulation) using the structurally-relaxed interfacial model as an initial structure, thereby generating time-series data of the interfacial model. The interfacial model illustrated in FIG. 2(d) corresponds to last data in the time-series data of the interfacial model. In the MD calculation, the lattice constant is fixed. In the MD calculation, 5000 steps are executed, each step having a duration of 2 femtoseconds (fs). In other words, the MD calculation is executed for 10 picoseconds (ps). Moreover, the MD calculation is executed while increasing the set temperature of the interfacial model at a fixed rate from 0 K to 300 K. In the MD calculation, the set temperature of the interfacial model may be maintained at a fixed temperature, or may be further increased to simulate, for example, a sintering reaction.

Subsequently, the output unit 13 of the information processing system 100 outputs progress information based on reaction information related to reaction obtained in accordance with the simulation by the processing unit 12. The output unit 13 outputs the progress information by using, as reaction information, an interfacial model corresponding to first data and an interfacial model corresponding to last data in the time-series data of the interfacial model obtained in accordance with the MD calculation. In other words, the reaction information includes first data indicating an interfacial model corresponding a start time of the simulation and second data indicating an interfacial model corresponding to an end time of the simulation.

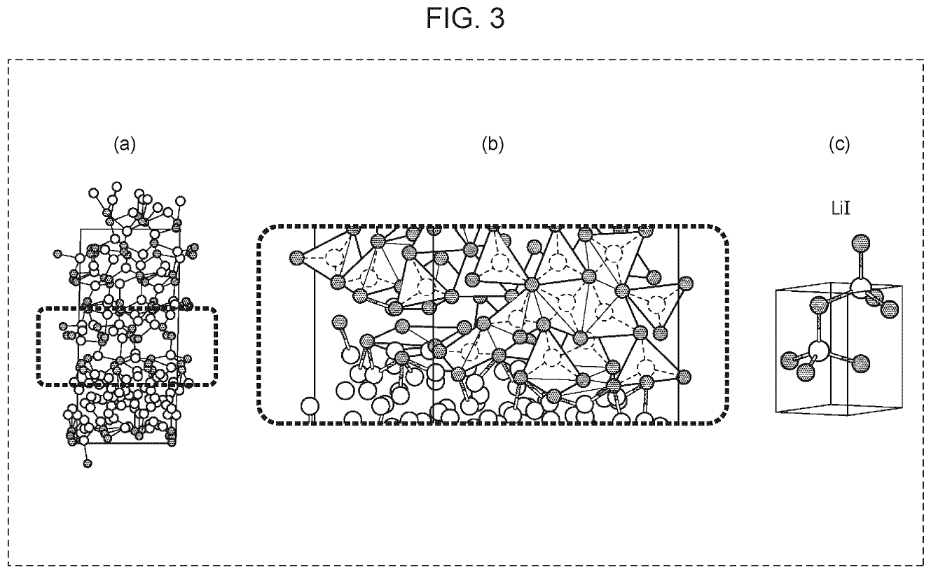

FIG. 3 schematically illustrates a calculation example of the degree of reaction progress. As illustrated in FIG. 3(a), the interfacial model has a region with a mixture of lithium atoms and iodine atoms, unlike the initial structure prior to the MD calculation. FIG. 3(b) is an enlarged view of a region surrounded by a dashed line in FIG. 3(a). FIG. 3(c) illustrates a known lithium-iodide crystal structure. As illustrated in FIG. 3(b), the region having the mixture of lithium atoms and iodine atoms includes many tetrahedral structures each having iodine atoms centered on a lithium atom. Each of these tetrahedral structures is extremely similar to the lithium-iodide crystal structure illustrated in FIG. 3(c).

In other words, when the interfacial model illustrated in FIG. 3 is displayed on the display 3, the user can visually check the interfacial model to determine that the iodine atoms existing in the initial structure have all reacted with the lithium atoms and that a lithium iodide has occurred as a reaction product.

The user can visually calculate that, in the interfacial model illustrated in FIG. 3, the volume of the region where the lithium iodide is produced, that is, a volume V of the reaction product, is equal to 4293 [Å³]. Furthermore, the number of lithium-iodide crystal structures produced is 72, which corresponds to the number of iodine atoms, since all iodine atoms have reacted. Therefore, with the input unit 2 receiving an input of the volume of the reaction product and the number of reaction products, the output unit 13 can calculate the reaction rate. A reaction rate v is calculated to be equal to 72/V/N_{A}/10 ps≈2.79×10¹⁵ [mol/m³/s]. In this case, “N_{A}” denotes Avogadro's number. Therefore, the output unit 13 can output progress information including the reaction rate v. Accordingly, the process for outputting progress information may involve calculating the reaction rate v based on a difference between the start time and the end time of the simulation, and outputting the progress information including the calculated reaction rate v.

Although the output unit 13 calculates the reaction rate by using the information (i.e., the number of reaction products and the volume of the reaction product) visually obtained by the user in the example illustrated in FIG. 3, for example, if a more complex reaction product occurs or if an unknown reaction product occurs, it may possibly be difficult to accurately calculate the reaction rate with the above-described method. Furthermore, since the execution time of the MD calculation is set as the reaction time in the example illustrated in FIG. 3, the reaction time may possibly be estimated to be longer than the actual reaction time.

The following description relates to a process for calculating the reaction time by using the radial distribution function, which is a type of characteristic information indicating a characteristic of the interfacial model, and to a process for calculating the volume of the reaction product by using the coordination number, which is also a type of characteristic information, for possibly solving the aforementioned problems.

First, the process for calculating the reaction time by using the radial distribution function will be described. The radial distribution function of a certain atom indicates a correlation between the distance from the atom to another atom and the probability at which the other atom exists at the distance. The radial distribution function of the interfacial model is expressed by calculating an average of the radial distribution function of the atoms in the interfacial model, and is a characteristic of the interfacial model that facilitates the ascertainment of the distribution of distances between the atoms in the interfacial model.

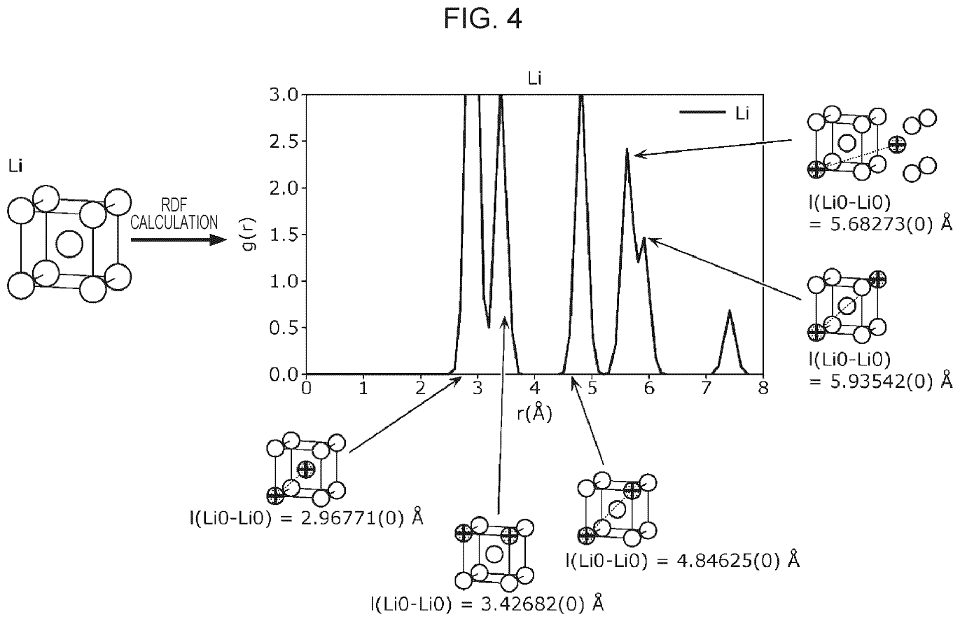

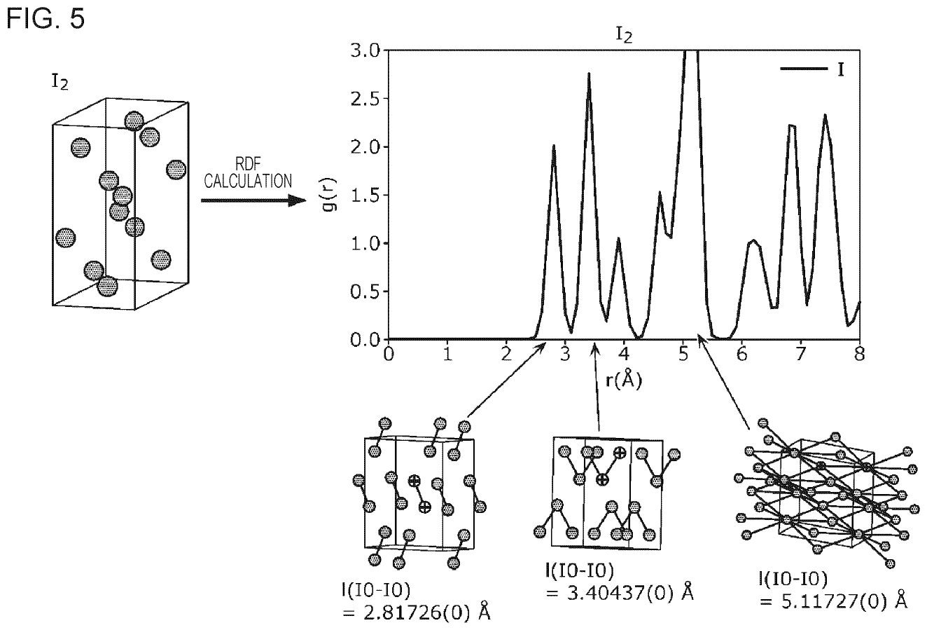

FIG. 4 illustrates an example of the radial distribution function of lithium metal. In a graph illustrated in FIG. 4, the ordinate axis denotes the radial distribution function “g(r)”, and the abscissa axis denotes an atom-to-atom distance “r”. The same applies to each of the graphs illustrated in FIG. 5 to FIG. 9 to be described below. As illustrated in FIG. 4, a peak of the radial distribution function occurs at every distance between lithium atoms. The radial distribution function may be defined by focusing on a certain atom and setting the number of atoms located therearound as a function of the distance r. In FIG. 4, 1(LiO—LiO) may be the distance between lithium atoms in a lithium crystal structure.

FIG. 5 illustrates an example of the radial distribution function of an iodine crystal. As illustrated in FIG. 5, a peak of the radial distribution function occurs at every distance between iodine atoms.

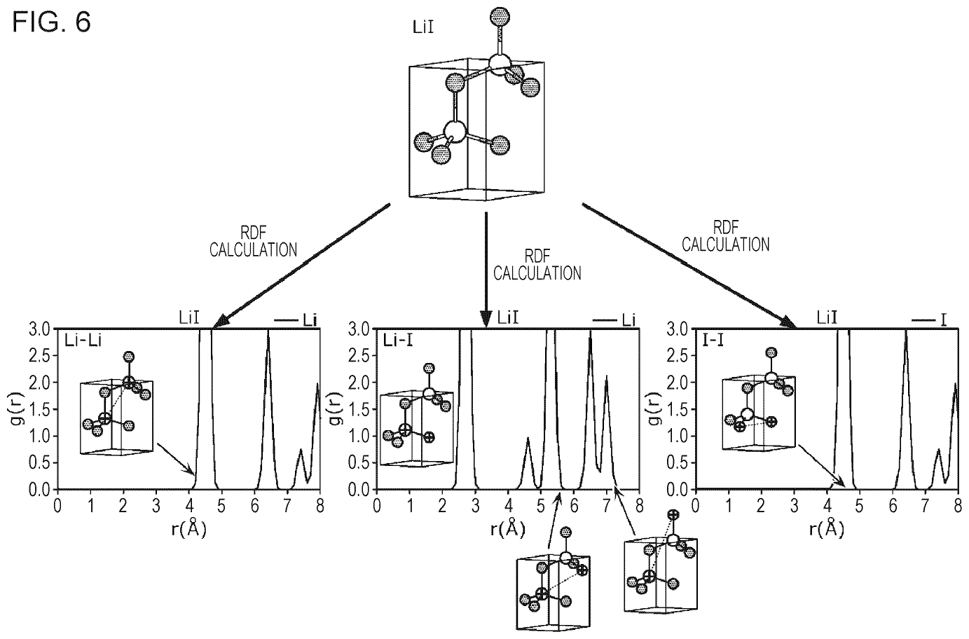

FIG. 6 illustrates an example of the radial distribution function of a lithium iodide crystal. As illustrated in FIG. 6, a peak of the radial distribution function occurs at every distance between lithium atoms. Moreover, a peak of the radial distribution function occurs at every distance between iodine atoms. Furthermore, a peak of the radial distribution function occurs at every distance between lithium and iodine atoms. Accordingly, when a crystal structure includes multiple types of atoms, the radial distribution function is defined for every combination of two atoms.

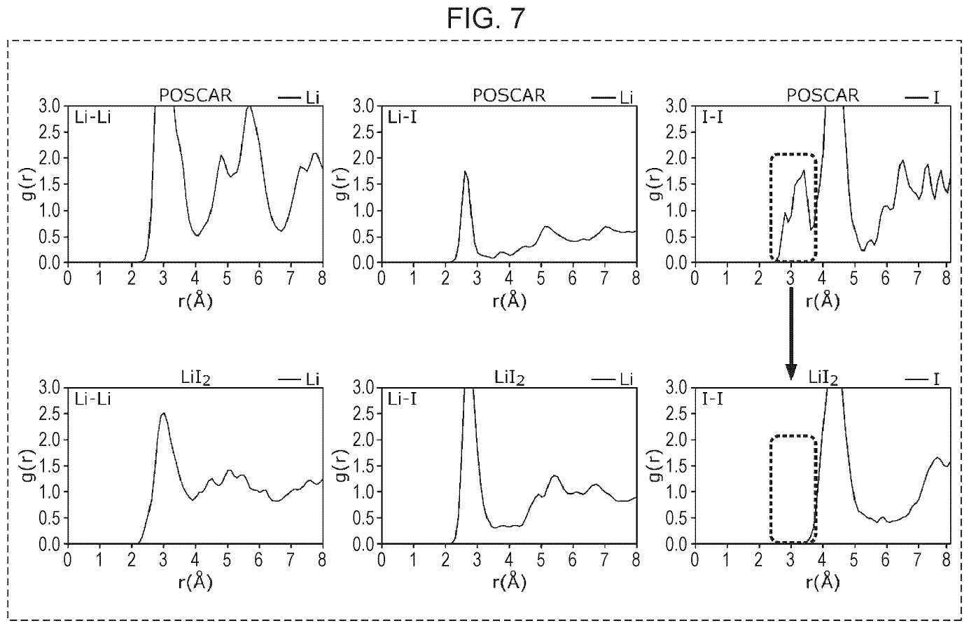

FIG. 7 schematically illustrates an example where a reaction end time is calculated by using the radial distribution function. The three upper graphs in FIG. 7 respectively illustrate, from left to right, the radial distribution function between lithium atoms in an interfacial model prior to an MD calculation, the radial distribution function between lithium and iodine atoms, and the radial distribution function between iodine atoms. The three lower graphs in FIG. 7 respectively illustrate, from left to right, the radial distribution function between lithium atoms in an interfacial model obtained after the MD calculation, the radial distribution function between lithium and iodine atoms, and the radial distribution function between iodine atoms.

When focusing on the radial distribution function between iodine atoms in FIG. 7, the peak of the radial distribution function existing prior to the MD calculation near where the atom-to-atom distance is 3 Å disappears after the MD calculation (see a region surrounded by a dashed line). This implies that, of the solid materials (lithium metal and iodine crystal), the iodine crystal has been completely consumed and has finished reacting.

In other words, the output unit 13 (in the process for outputting progress information) can estimate that the time at which a predetermined peak included in the radial distribution function at the start time of the simulation has disappeared is the reaction end time, and can output progress information including the estimated reaction end time. The output unit 13 (in the process for outputting progress information) may estimate that, for example, the time at which a new peak emerges in the radial distribution function during the simulation and the peak no longer fluctuates over time is the reaction end time.

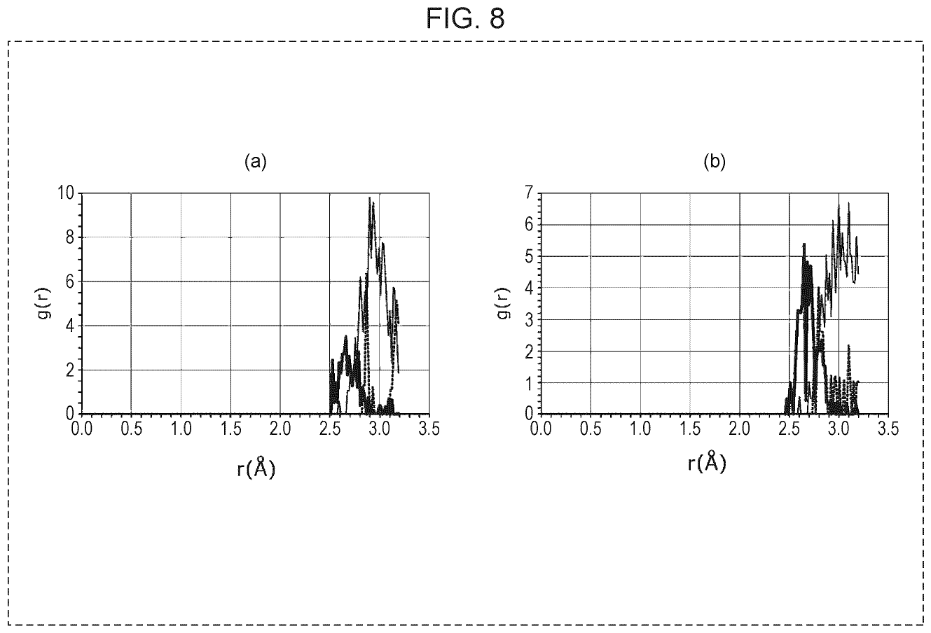

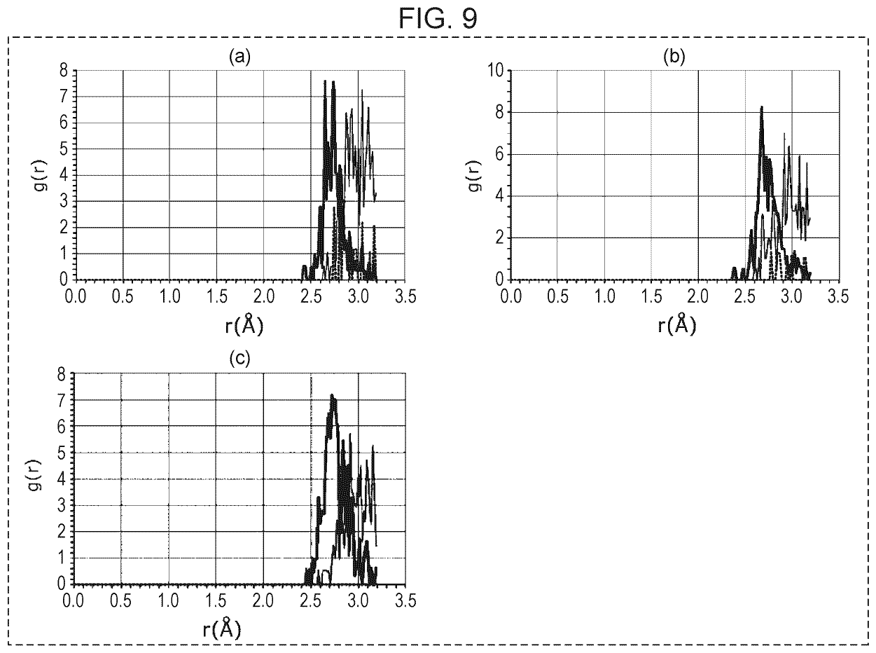

FIG. 8 and FIG. 9 schematically illustrate examples where the reaction end time is calculated by using the radial distribution function. FIG. 8 and FIG. 9 each illustrate time-series data of a characteristic (i.e., the radial distribution function) of an interfacial model obtained in accordance with an MD calculation. In each of FIG. 8 and FIG. 9, a solid line denotes the radial distribution function between lithium atoms, a dotted line denotes the radial distribution function between iodine atoms, and a thick solid line denotes the radial distribution function between lithium and iodine atoms. FIG. 8(a) illustrates data at the starting point of the MD calculation, and FIG. 8(b) illustrates data obtained 1 ps after the start of the MD calculation. FIG. 9(a) illustrates data obtained 2 ps after the start of the MD calculation, FIG. 9(b) illustrates data obtained 3 ps after the start of the MD calculation, and FIG. 9(c) illustrates data obtained 4 ps after the start of the MD calculation. The ordinate axis of the graph illustrated in each of FIG. 8 and FIG. 9 denotes the radial distribution function “g(r)”, whereas the abscissa axis denotes the atom-to-atom distance (pair separation distance) “r”.

As illustrated in each of FIG. 8 and FIG. 9, when focusing on the radial distribution function between iodine atoms, the peak occurring near where the atom-to-atom distance is 3 Å gradually decreases over time. This indicates that the iodine crystal is consumed, that is, the reaction is progressing. As illustrated in FIG. 9(c), the aforementioned peak disappears 4 ps after the start of the MD calculation. Therefore, the output unit 13 (in the process for outputting progress information) estimates that the time 4 ps after the start of the MD calculation is the end time.

Next, the process for calculating the volume of the reaction product by using the coordination number will be described. First, the output unit 13 uses the interfacial model at the aforementioned reaction end time to calculate the coordination number of each of the atoms (i.e., the lithium atoms and the iodine atoms) included in the interfacial model. For example, the coordination number can be calculated by using an appropriate algorithm, such as CrystalNN implemented in pymatgen. With regard to this algorithm, refer to the document (Hillary Pan, Alex M. Ganose, Matthew Horton, Muratahan Aykol, Kristin A. Persson, Nils E. R. Zimmermann, and Anubhav Jain, Inorg. Chem. 2021, 60, 3, 1590-1603, “Benchmarking Coordination Number Prediction Algorithms on Inorganic Crystal Structures”).

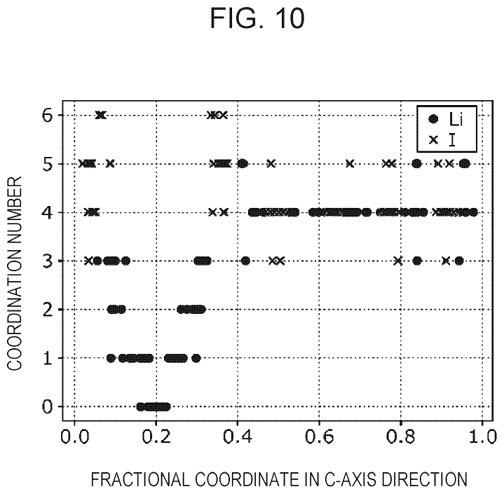

FIG. 10 schematically illustrates an example where the volume of the reaction product is calculated by using the coordination number. FIG. 10 illustrates a graph plotting the calculated coordination number against a c-axis coordinate. In FIG. 10, the ordinate axis denotes the coordination number, whereas the abscissa axis denotes a fractional coordinate in a c-axis direction. In FIG. 10, a circle mark denotes the number of iodine atoms coordinated to a lithium atom, and a cross mark denotes the number of lithium atoms coordinated to an iodine atom.

As already described above, iodine atoms existing in a solid material all exist within a reaction product after the end of a reaction. In FIG. 10, this corresponds to a state where, for any of the iodine atoms, the number of lithium atoms coordinated to the iodine atom is not zero. The coordination number is expressed by a non-negative integer by definition. In other words, a state where all iodine atoms in a solid material exist in a reaction product corresponds to a state where, for any of the iodine atoms, the number of lithium atoms coordinated to the iodine atom is greater than or equal to one in FIG. 10. An occupancy ratio of a region (referred to as “specific region” hereinafter) on the fractional coordinate in the c-axis direction where the number of lithium atoms coordinated to the iodine atom in the entire region is greater than or equal to one can be regarded as an occupancy ratio of the reaction product in the entire interfacial model.

Therefore, based on the occupancy ratio of the specific region in the entire region, the volume of the reaction product can be calculated. In other words, the output unit 13 (in the process for outputting progress information) can calculate the volume of the reaction product produced by the reaction based on the coordination number of each atom included in the interfacial model with respect to a predetermined crystal axis (i.e., the c axis), and can output the progress information including the calculated volume of the reaction product.

In the example illustrated in FIG. 10, the specific region includes a range of c=[0.0, 0.1] and a range of c=[0.35, 1.0]. Therefore, the output unit 13 can calculate that the occupancy ratio of the specific region in the entire region is 0.75. Then, by multiplying the ratio by the volume of the interfacial model, the output unit 13 can calculate the volume of the reaction product. The volume V of the reaction product is calculated as follows: V=5448×0.75=4086 [Å]. The output unit 13 can calculate the reaction rate v as follows: v=72/V/N_{A}/4 ps≈7.32×10¹⁵ [mol/m³/s].

Accordingly, by using the characteristic information indicating a characteristic of the interfacial model, the information processing system 100 performs a comparison with a case where information visually obtained by the user is used, so as to be capable of accurately calculating the reaction time and the reaction rate. By using the characteristic information, the information processing system 100 can calculate the reaction time and the reaction rate even when, for example, a more complex reaction product occurs or an unknown reaction product occurs.

### Operation

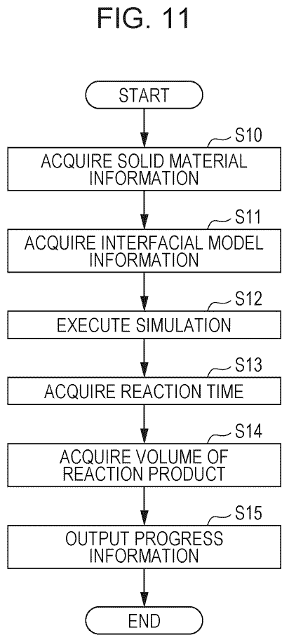

The operation (i.e., the information processing method) of the information processing system 100 according to the embodiment will be described below. FIG. 11 is a flowchart illustrating an operation example of the information processing system 100 according to the embodiment.

### Step S10

The acquiring unit 11 acquires solid material information. In the embodiment, the solid material information includes first solid material information and second solid material information. The solid material information is acquired by the acquiring unit 11 by being input by the user via the input unit 2.

### Step S11

The acquiring unit 11 acquires interfacial model information. In the embodiment, the acquiring unit 11 acquires first structural model information and second structural model information respectively based on the first solid material information and the second solid material information received via the input unit 2. Then, the acquiring unit 11 generates an interfacial model based on the acquired first structural model information and second structural model information, thereby acquiring the interfacial model.

### Step S12

The processing unit 12 executes a simulation based on the interfacial model information acquired by the acquiring unit 11. In the embodiment, the processing unit 12 executes a structural relaxation calculation on the interfacial model based on the interfacial model information acquired by the acquiring unit 11, and executes a simulation on the structurally-relaxed interfacial model. Moreover, the processing unit 12 executes an MD calculation as the simulation.

### Step S13

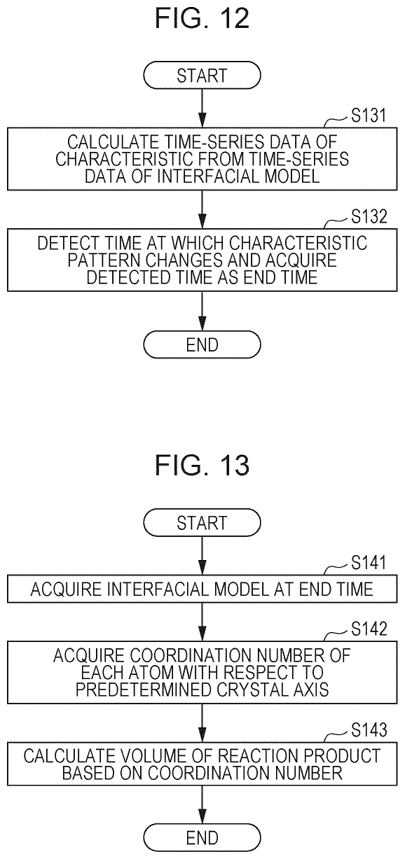

The output unit 13 acquires a reaction time based on reaction information related to reaction obtained in accordance with the simulation executed by the processing unit 12. For example, when the user determines that a reaction product has occurred by viewing the interfacial model displayed on the display 3, the output unit 13 acquires the execution time of the simulation as the reaction time. Furthermore, for example, the output unit 13 calculates a reaction end time by using a characteristic of the interfacial model (i.e., the radial distribution function), so as to acquire the reaction time. An example of operation for calculating the reaction end time will be described below with reference to FIG. 12. FIG. 12 is a flowchart illustrating the example of operation performed by the information processing system 100 according to the embodiment for calculating the reaction end time.

### Step S131

First, the output unit 13 calculates time-series data of a characteristic from time-series data of the interfacial model obtained in accordance with the simulation. In this case, the output unit 13 calculates time-series data of the radial distribution function of each atom included in the interfacial model from the time-series data of the interfacial model.

### Step S132

Subsequently, the output unit 13 detects a time at which the characteristic pattern changes, and acquires the detected time as the end time. In this case, the output unit 13 detects a time at which a predetermined peak included in the radial distribution function at the start time of the simulation disappears, and acquires the detected time as the reaction end time.

### Step S14

Referring back to FIG. 11, the output unit 13 acquires the volume of the reaction product based on the reaction information related to reaction obtained in accordance with the simulation executed by the processing unit 12. In this case, for example, when the user determines that a reaction product has occurred by viewing the interfacial model displayed on the display 3, the output unit 13 acquires the volume of the reaction product input by the user via the input unit 2. Furthermore, for example, the output unit 13 calculates the volume of the reaction product by using a characteristic (i.e., the coordination number) of the interfacial model, so as to acquire the volume of the reaction product. An example of operation for calculating the volume of the reaction product will be described below with reference to FIG. 13. FIG. 13 is a flowchart illustrating the example of operation performed by the information processing system 100 according to the embodiment for calculating the volume of the reaction product.

### Step S141

First, the output unit 13 acquires the interfacial model at the reaction end time.

### Step S142

Subsequently, the output unit 13 calculates and acquires the coordination number of each atom included in the interfacial model with respect to a predetermined crystal axis (i.e., the c axis).

### Step S143

Then, the output unit 13 calculates the volume of the reaction product based on the calculated coordination number. In this case, the output unit 13 calculates an occupancy ratio of the reaction product in the entire interfacial model based on the coordination number and multiplies the ratio by the volume of the interfacial model, thereby calculating the volume of the reaction product.

### Step S15

Referring back to FIG. 11, the output unit 13 outputs progress information. In this case, the output unit 13 calculates a reaction rate based on the reaction time acquired in step S13 and the volume of the reaction product acquired in step S14, and outputs progress information including the calculated reaction rate.

If the interfacial model corresponding to the end time of the simulation does not include a reaction product, the output unit 13 does not execute step S13 and step S14 and outputs progress information including information indicating that a reaction has not occurred. In other words, if the interfacial model indicated by second data (i.e., the interfacial model corresponding to the end time of the simulation) includes a reaction occurrence region having a mixture of atoms contained in the two or more solid materials, the output unit 13 outputs progress information including information indicating that a reaction has occurred. In contrast, if the interfacial model indicated by the second data does not include the reaction occurrence region, the output unit 13 outputs progress information including information indicating that a reaction has not occurred.

### Usage Example

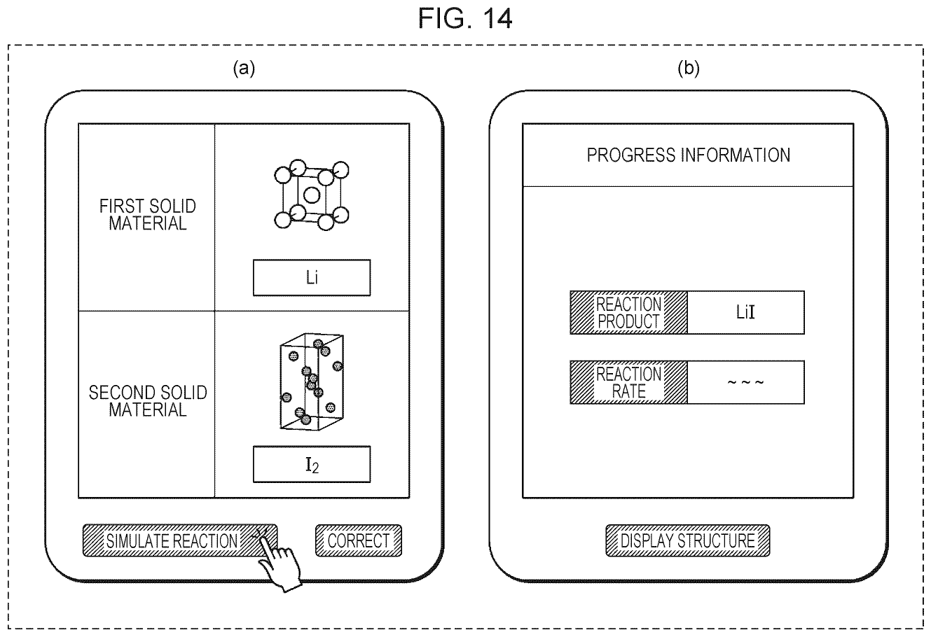

A usage example of the information processing system 100 according to the embodiment will be described below. FIG. 14 illustrates an example of a first image and a second image displayed on the display 3 in the embodiment. FIG. 14(a) illustrates an example of the first image displayed on the display 3 by the display controller 30. The first image is used for receiving an input of first solid material information indicating the first solid material and an input of second solid material information indicating the second solid material. In the embodiment, the first image includes a first input region used for inputting the first solid material information, a second input region used for inputting the second solid material information, a “simulate reaction” icon, and a “correct” icon.

The first input region displays a textbox for inputting the material name (or the composition formula) of the first solid material, as well as the first structural model corresponding to the input first solid material. The second input region displays a textbox for inputting the material name (or the composition formula) of the second solid material, as well as the second structural model corresponding to the input second solid material. As already described above, if the user has input the crystal structures of the first solid material and the second solid material to the input unit 2, the input crystal structure of the first solid material and the input crystal structure of the second solid material are displayed as the first structural model and the second structural model, respectively, on the display 3. In contrast, if the crystal structures of the first solid material and the second solid material are not input to the input unit 2, a first structural model and a second structural model respectively corresponding to the first solid material and the second solid material and acquired from, for example, an external database are displayed on the display 3.

The user inputs the material names (or the composition formulas) of the first solid material and the second solid material to the first input region and the second input region, respectively, and selects the “simulate reaction” icon. Accordingly, the processing unit 12 executes a simulation, and the output unit 13 subsequently outputs progress information. If the user desires to correct input information, the user can appropriately correct the input content by selecting the “correct” icon.

FIG. 14(b) illustrates an example of the second image displayed on the display 3 by the display controller 30. The second image indicates progress information indicating the degree of reaction progress between the first solid material and the second solid material and generated based on the input first solid material information and second solid material information. The second image is displayed on the display 3 after the user selects the “simulate reaction” icon in the first image. The second image includes the name (or the composition formula) of a reaction product produced in accordance with a reaction between the first solid material and the second solid material, the reaction rate, and a “display structure” icon. When the user selects the “display structure” icon, the display 3 displays an interfacial model obtained after the simulation.

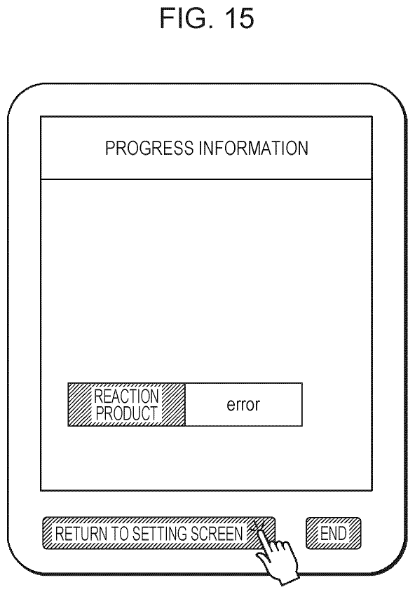

If a reaction product is not produced as a result of the simulation executed by the processing unit 12, the display 3 displays the second image illustrated in FIG. 15. FIG. 15 illustrates another example of the second image displayed on the display 3 in the embodiment. In the example illustrated in FIG. 15, the second image includes a text string “error” indicating that a reaction product has not been produced, a “return to setting screen” icon, and an “end” icon. When the user selects the “return to setting screen” icon, the display 3 displays the first image again. When the user selects the “end” icon, the operation performed by the information processing system 100 ends.

As illustrated in FIG. 14(b) and FIG. 15, the user can ascertain the degree of reaction progress between the first solid material and the second solid material by viewing the second image. By viewing the second image, the user can ascertain whether or not a reaction has occurred. Moreover, by viewing the second image, the user can ascertain the reaction rate if a reaction has occurred.

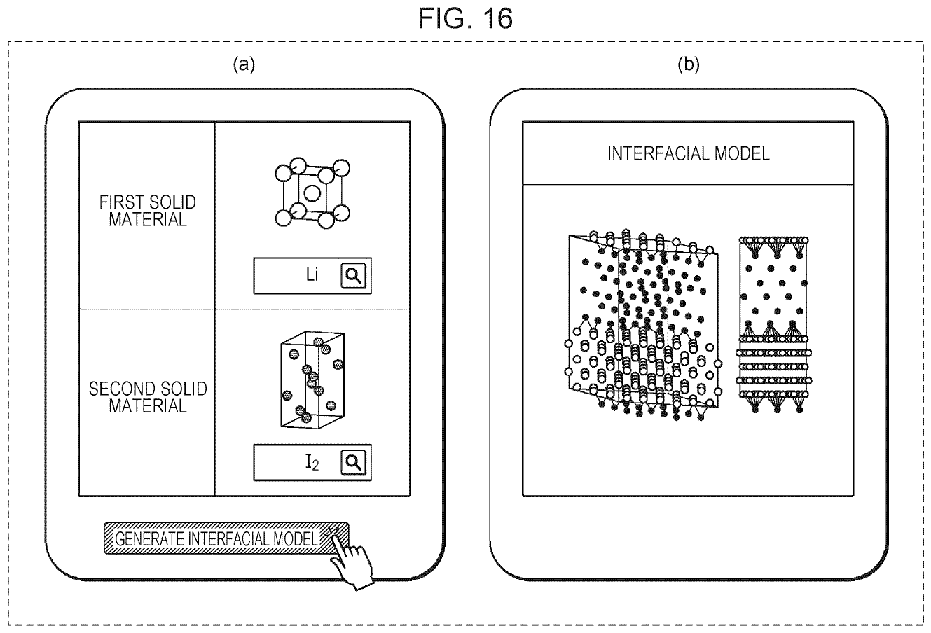

FIG. 16 illustrates an example of the first image and a third image displayed on the display 3 in the embodiment. FIG. 16(a) illustrates an example of the first image displayed on the display 3 by the display controller 30. The first image illustrated in FIG. 16(a) is different from the first image illustrated in FIG. 14(a) in that it includes a “generate interfacial model” icon in place of the “simulate reaction” icon and the “correct” execution icon. The user inputs the material names (or the composition formulas) of the first solid material and the second solid material respectively to the first input region and the second input region, and selects the “generate interfacial model” icon. Accordingly, the acquiring unit 11 generates an interfacial model based on the input first solid material information and second solid material information. This interfacial model will be referred to as “first interfacial model”.

The first interfacial model is generated as a result of the first solid material, which has a first structure including first atoms, and the second solid material, which has a second structure including second atoms, coming into contact with each other, and includes a boundary region between the first structure and the second structure. The first atoms are lithium atoms, the first structure is a lithium-metal crystal structure, the second atoms are iodine atoms, and the second structure is an iodine crystal structure.

FIG. 16(b) illustrates an example of the third image displayed on the display 3 by the display controller 30. The third image indicates first interfacial model information. As illustrated in FIG. 16(b), the third image includes an image expressing the interfacial model (first interfacial model) generated by the acquiring unit 11. By viewing the third image, the user can ascertain what kind of an interfacial model is used to simulate a reaction.

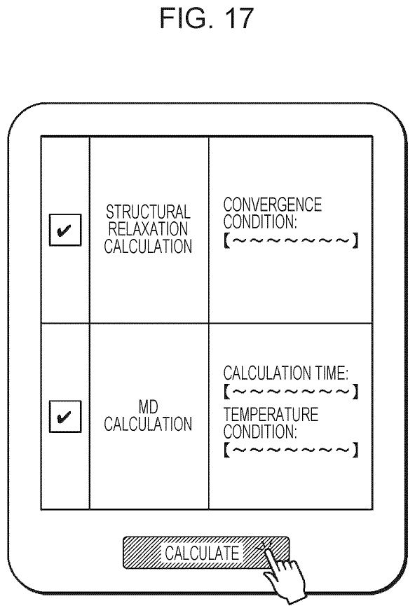

FIG. 17 illustrates an example of a fourth image displayed on the display 3 in the embodiment. The display controller 30 may cause the display 3 to display the fourth image after causing the display 3 to display the third image, or may cause the display 3 to display the fourth image alongside the third image. The fourth image is used for receiving an input of calculation method information indicating a calculation method executable on the interfacial model (first interfacial model) generated by the acquiring unit 11. In the embodiment, the fourth image includes a first setting region used for inputting settings for a structural relaxation calculation, a second setting region used for inputting settings for an MD calculation, and a “calculate” icon.

The first setting region displays a checkbox used for selecting whether or not to execute a structural relaxation calculation, and a text string indicating a convergence condition for the structural relaxation calculation. The convergence condition for the structural relaxation calculation may be appropriately changeable by an input from the user. The second setting region displays a checkbox used for selecting whether or not to execute an MD calculation, and text strings indicating the calculation time and the temperature condition for the MD calculation. The temperature condition for the MD calculation may be appropriately changeable by an input from the user.

The user selects a desired calculation method in each of the first setting region and the second setting region, and selects the “calculate” icon. Accordingly, the processing unit 12 executes at least one of the structural relaxation calculation or the MD calculation. If the processing unit 12 executes the MD calculation, the output unit 13 outputs progress information. By viewing the fourth image, the user can select a desired calculation method to be executed on the interfacial model.

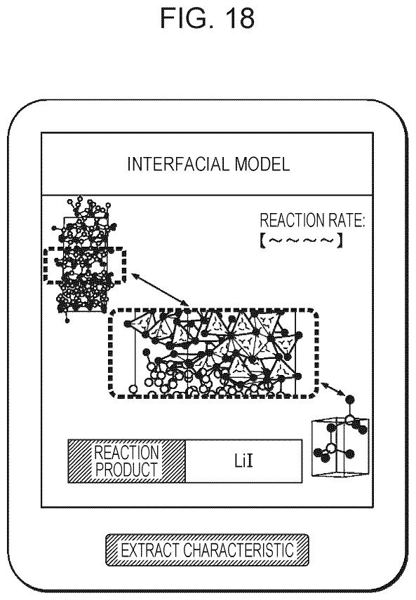

FIG. 18 illustrates an example of a fifth image displayed on the display 3 in the embodiment. The display controller 30 causes the display 3 to display the fifth image upon completion of the simulation by the processing unit 12. The fifth image indicates second interfacial model information generated based on the input calculation method information. As illustrated in FIG. 18, the fifth image includes an image expressing an interfacial model (second interfacial model) obtained after the simulation (i.e., MD calculation) executed by the processing unit 12, the name (or the composition formula) of a reaction product, the reaction rate, and an “extract characteristic” icon. If a reaction product is not produced as a result of the simulation by the processing unit 12, the name of a reaction product and the reaction rate are not included in the fifth image.

When the user selects the “extract characteristic” icon, the display 3 displays time-series data of a characteristic (e.g., the radial distribution function) of the interfacial model. By viewing the fifth image, the user can ascertain the interfacial model obtained after the simulation.

### Advantages

As described above, the information processing system 100 (information processing method) according to the embodiment executes a simulation of a reaction between two or more solid materials, so as to be capable of outputting progress information indicating the degree of reaction progress. Therefore, the information processing system 100 according to the embodiment is advantageous in being able to readily estimate the degree of reaction progress instead of simply estimating a reaction product of the two or more solid materials. Consequently, the information processing system 100 according to the embodiment is advantageous in that the user can readily ascertain how the two or more solid materials react with each other, including the reaction rate of the two or more solid materials, or whether the two or more solid materials do not react in the first place.

### Modifications

Although the information processing system (information processing method) according to one or more aspects of the present disclosure has been described above based on the embodiment, the present disclosure is not limited to the above embodiment. An embodiment achieved by applying various types of modifications conceivable by a skilled person to the above embodiment may be included in the present disclosure so long as the embodiment does not depart from the scope of the present disclosure.

For example, the output unit 13 (in the process for outputting progress information) may calculate the reaction end time by using a SOAP descriptor as characteristic information indicating a characteristic of an interfacial model. In this case, the SOAP descriptor is used for expressing a local atomic environment. For example, the SOAP descriptor captures the local chemical environment around an atom, is encoded as a mathematical representation, and is used for comparing different atomic arrangements.

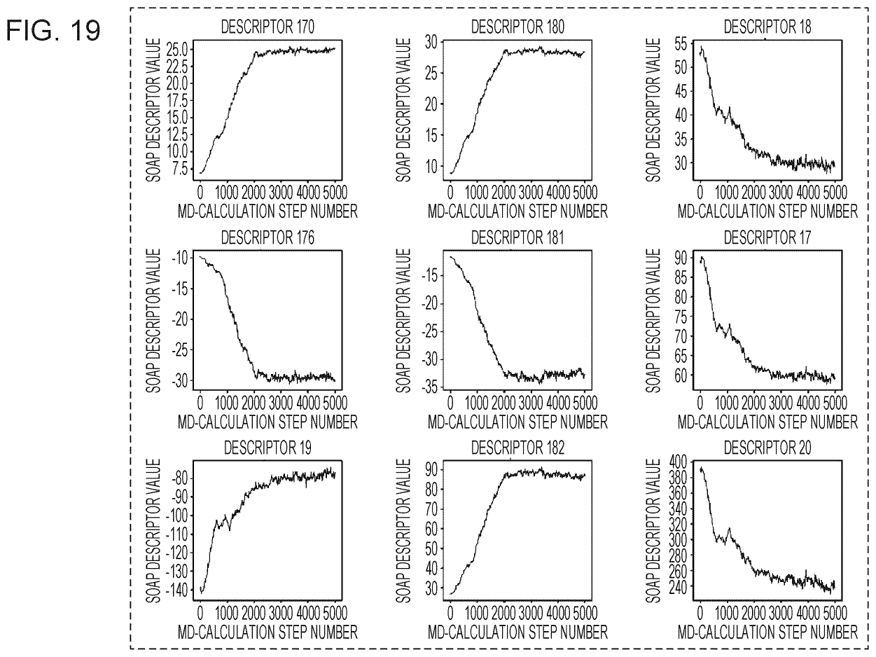

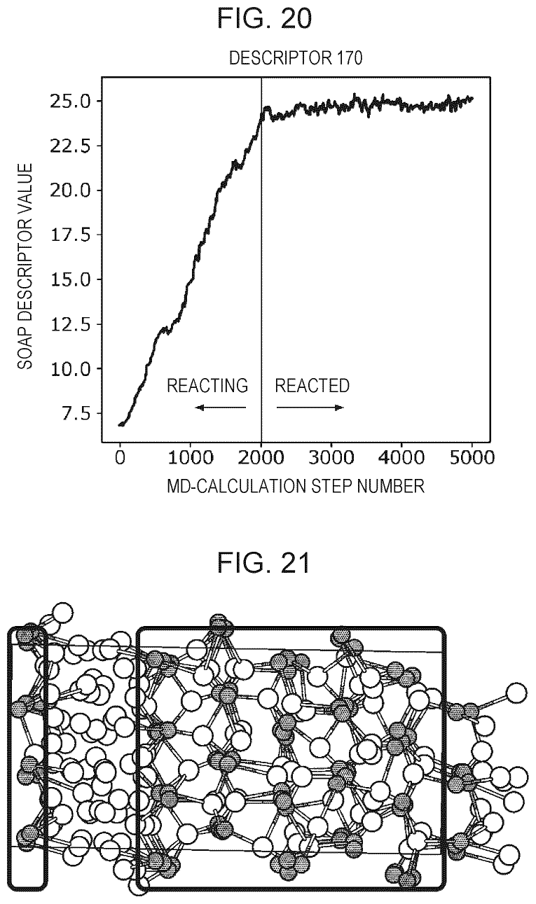

The output unit 13 calculates time-series data of a large number (e.g., several hundreds) of SOAP descriptors for an interfacial model, and extracts time-series data with a relatively large temporal variation in a SOAP descriptor value from the calculated time-series data of the large number of SOAP descriptors. FIG. 19 schematically illustrates an example where the reaction end time is calculated by using SOAP descriptors. FIG. 20 schematically illustrates an example where the reaction end time is calculated by using SOAP descriptors. FIG. 19 illustrates nine pieces of time-series data each with a relatively large temporal variation in the SOAP descriptor value. FIG. 20 illustrates an example of time-series data of the SOAP descriptors. In each of the graphs illustrated in FIG. 19 and FIG. 20, the ordinate axis denotes the SOAP descriptor value, whereas the abscissa axis denotes the MD-calculation step number, that is, the calculation time. As illustrated in FIG. 19 and FIG. 20, in the time-series data of the many SOAP descriptors, the SOAP descriptor value saturates at about the 2000-th step. Therefore, the output unit 13 can estimate that the reaction is completed at the 2000-th step of the MD calculation, that is, 4 ps from the start of the simulation. The output unit 13 may calculate the step number at which the SOAP descriptor value saturates in each of the pieces of time-series data of the many SOAP descriptors, and may estimate a representative value (e.g., an average value, a mode value, or a median value) of the step number as the reaction end time.

For example, the output unit 13 (in the process for outputting progress information) may calculate the volume of a reaction product by using a histogram as characteristic information indicating a characteristic of an interfacial model. FIG. 21 is a diagram for explaining a reaction occurrence region in the interfacial model. FIG. 21 illustrates the interfacial model after a reaction using lithium metal as the first solid material and an iodine crystal as the second solid material. In FIG. 21, there are many lithium iodides as a reaction product in a region surrounded by a solid line, and this region corresponds to the reaction occurrence region. If the reaction occurrence region (i.e., a region having a mixture of lithium ions and iodine atoms) and a region (i.e., a region having only lithium ions) other than the reaction occurrence region can be quantitatively distinguished from each other, the ratio of the reaction occurrence region to the entire interfacial model can be calculated, so that the volume of the reaction product can be calculated.

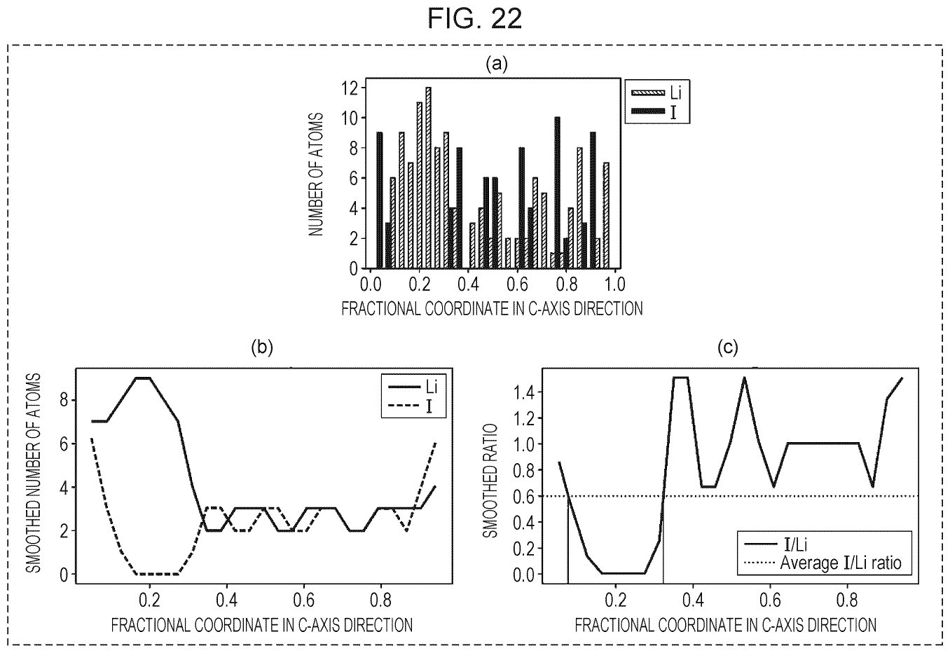

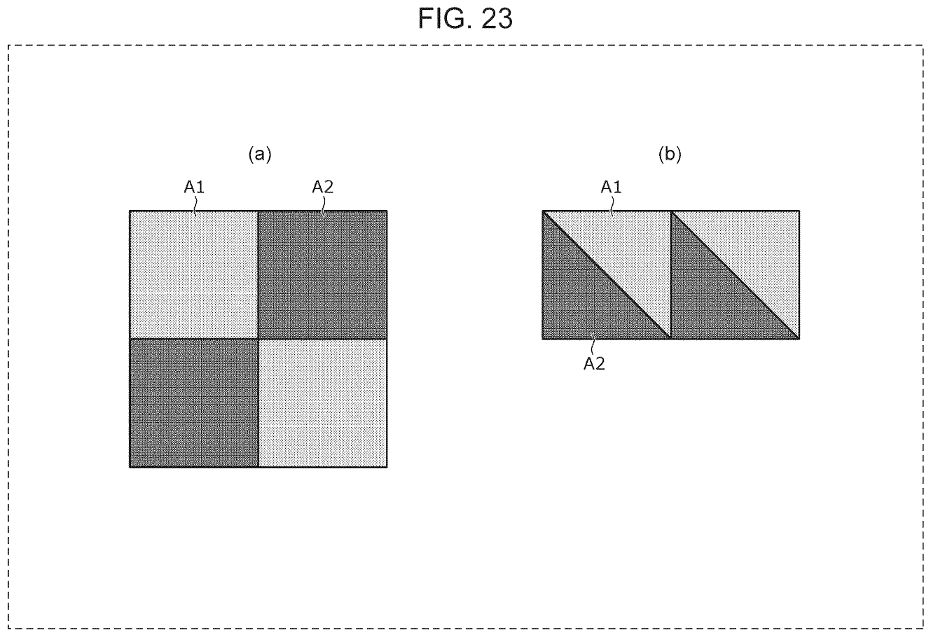

FIG. 22 schematically illustrates an example where the volume of a reaction product is calculated by using a histogram. FIG. 22(a) illustrates a histogram generated by the output unit 13 based on the interfacial model illustrated in FIG. 21. This histogram indicates each of the number of lithium atoms and the number of iodine atoms included in the interfacial model illustrated in FIG. 21 on the predetermined crystal axis (i.e., the c axis) by using 25 bins. As illustrated in FIG. 22(a), in this histogram, since the reaction occurrence region also includes a region where iodine atoms exist and a region where iodine atoms do not exist, it is difficult to accurately distinguish the reaction occurrence region from other regions. Although it is conceivable to expand the bin width of the histogram, this would reduce the resolution of the reaction occurrence region, thus still making it difficult to accurately distinguish the reaction occurrence region from other regions.

In view of this, the output unit 13 smooths the histogram illustrated in FIG. 22(a) by converting the histogram using a Gaussian function with an appropriate standard deviation (σ=1.2) (see FIG. 22(b)), and calculates a ratio between the number of iodine atoms and the number of lithium atoms from the Gaussian function (see FIG. 22(c)). In FIG. 22(c), a solid line denotes a ratio (referred to as “first ratio” hereinafter) of the number of iodine atoms to the number of lithium atoms, and a dashed line denotes a ratio (referred to as “second ratio” hereinafter) of the number of iodine atoms to the number of lithium atoms in the entire interfacial model. Then, the output unit 13 estimates that a range in which the first ratio falls below the second ratio is the reaction occurrence region. In the example illustrated in FIG. 22(c), the reaction occurrence region includes a range of c=[0.0, 0.08] and a range of c=[0.36, 1.0], so that the ratio of the reaction occurrence region to the entire interfacial model can be calculated to be about 0.75.

Furthermore, for example, the output unit 13 (in the process for outputting progress information) may estimate the reaction occurrence region by analyzing the image of the interfacial model illustrated in FIG. 21 by using an image recognition technique, such as semantic segmentation.

Furthermore, for example, although the interfacial model is obtained by superimposing any one crystal plane of the crystal structure of the first solid material and any one crystal plane of the crystal structure of the second solid material in the embodiment, the interfacial model is not limited to this. Examples of the interfacial model will be described below.

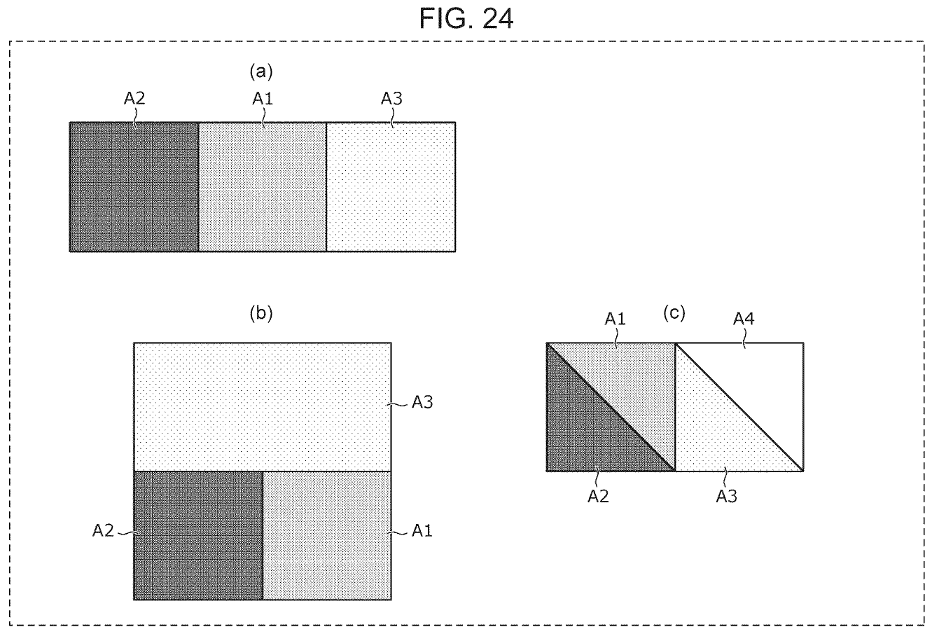

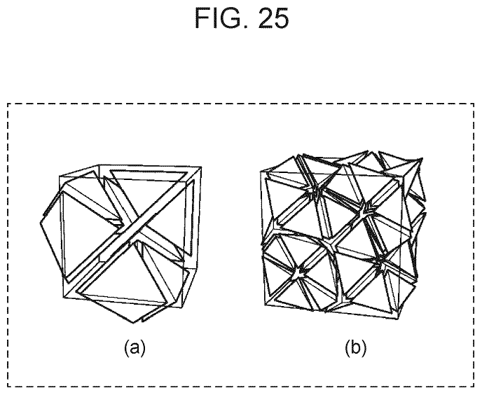

FIG. 23 illustrates an example of the interfacial model. In FIG. 23, “A1” denotes a pattern expressing the crystal structure of the first solid material based on a two-dimensional plane, and “A2” denotes a pattern expressing the crystal structure of the second solid material based on a two-dimensional plane. The same applies to FIG. 24 to be described below. As illustrated in FIG. 23(a) and FIG. 23(b), the interfacial model may be a model obtained by superimposing each of two crystal planes of a certain crystal structure on a crystal plane of another solid material.

FIG. 24 illustrates another example of the interfacial model. In FIG. 24, “A3” denotes a pattern expressing the crystal structure of a third solid material based on a two-dimensional plane, and “A4” denotes a pattern expressing the crystal structure of a fourth solid material based on a two-dimensional plane. As illustrated in FIG. 24(a), FIG. 24(b), and FIG. 24(c), the interfacial model may be a model obtained by superimposing crystal planes of three or more solid materials. As illustrated in FIG. 24(b), the interfacial model may be a model obtained by superimposing crystal planes of two or more solid materials on a crystal plane of a certain solid material. As illustrated in FIG. 24(c), the interfacial model may be a model obtained by superimposing crystal planes of two different solid materials at each of two crystal planes of a certain solid material.

FIG. 25 illustrates another example of the interfacial model. In FIG. 25, tetrahedrons denote crystal structures of different solid materials. As illustrated in FIG. 25(a) and FIG. 25(b), the interfacial model may be a three-dimensional model obtained by superimposing crystal planes of many solid materials.

The information processing system includes the acquiring unit 11, the processing unit 12, and the output unit 13 in the above embodiment, but is not limited to this configuration. For example, in the above embodiment, the information processing system may include the display controller 30 and the display 3, as denoted by “100A” in FIG. 1.

In the above embodiment, each component may be constituted of dedicated hardware or may be implemented by executing a software program suitable for the component. Each component may be implemented by causing a program executer, such as a central processing unit (CPU) or a processor, to read and execute a software program recorded on a recording medium, such as a hard disk or a semiconductor memory.

The following cases are also included in the present disclosure.

(1) At least one device described above is specifically a computer system including a microprocessor, a read-only memory (ROM), a random access memory (RAM), a hard disk unit, a display unit, a keyboard, a mouse, or the like. The RAM or the hard disk unit has a computer program stored therein. The microprocessor operates in accordance with the computer program, so that the at least one device achieves its function. In order to achieve a predetermined function, the computer program is a combination of command codes indicating commands for the computer.

(2) The components included in the at least one device may partially or entirely be constituted of a single system large scale integration (LSI). A system LSI is an ultra-multifunctional LSI manufactured by integrating components onto a single chip, and is specifically a computer system that includes a microprocessor, a ROM, a RAM, or the like. The RAM has a computer program stored therein. The microprocessor operates in accordance with the computer program, so that the system LSI achieves its function.

(3) The components included in the at least one device may partially or entirely be constituted of an integrated circuit (IC) card or a single module attachable to and detachable from the device. The IC card or the module is a computer system that includes a microprocessor, a ROM, a RAM, or the like. The IC card or the module may include the aforementioned ultra-multifunctional LSI. The microprocessor operates in accordance with a computer program, so that the IC card or the module achieves its function. The IC card or the module may be tamper-resistant.

(4) The present disclosure may be the method described above. Moreover, the present disclosure may be a computer program implemented by causing a computer to execute the method, or may be a digital signal constituted of a computer program.

The present disclosure may be achieved by recording a computer program or a digital signal onto a computer-readable recording medium, such as a flexible disk, a hard disk, a compact disc-read only memory (CD-ROM), a digital versatile disc-read only memory (DVD-ROM), a digital versatile disc-random access memory (DVD-RAM), a Blu-ray (registered trademark) disc, or a semiconductor memory. The present disclosure may be a digital signal recorded on any of these recording media.

The present disclosure may be achieved by transmitting a computer program or a digital signal via an electrical communication line, a wireless or wired communication line, a network represented by the Internet, data broadcasting, or the like.

The present disclosure may be implemented by another independent computer system by recording and transferring a program or a digital signal onto a recording medium or by transferring a program or a digital signal via a network or the like.

The present disclosure is advantageous in being able to properly assist a user in predicting a reaction between two or more solid materials, and is applicable to a computer or a system for displaying information about the prediction process.

What is claimed is:

1. An information processing method executed by a computer, the information processing method comprising:
acquiring interfacial model information indicating an interfacial model of two or more solid materials;
executing a simulation of a reaction between the two or more solid materials based on the acquired interfacial model information; and
outputting progress information indicating a degree of progress of the reaction based on reaction information related to the reaction obtained by the simulation.

2. The information processing method according to claim 1,
wherein the outputting the progress information comprises outputting the progress information including characteristic information indicating a characteristic of a structure generated by the reaction.

3. The information processing method according to claim 1,
wherein the two or more solid materials comprise a first solid material and a second solid material,
wherein the acquiring the interfacial model information comprises:
acquiring first structural model information and second structural model information, the first structural model information indicating a first structural model of a structure of the first solid material, the second structural model information indicating a second structural model of a structure of the second solid material; and
generating the interfacial model obtained by combining the first structural model and the second structural model based on the acquired first structural model information and the acquired second structural model information.

4. The information processing method according to claim 1,
wherein the simulation is a molecular dynamics simulation, and
wherein the reaction information includes first data indicating the interfacial model corresponding to a start time of the simulation and second data indicating the interfacial model corresponding to an end time of the simulation.

5. The information processing method according to claim 4,
wherein the outputting the progress information comprises:
outputting the progress information including information indicating that the reaction has occurred when the interfacial model indicated by the second data includes a reaction occurrence region including a mixture of atoms respectively contained in the two or more solid materials; and
outputting the progress information including information indicating that the reaction has not occurred when the interfacial model indicated by the second data does not include the reaction occurrence region.

6. The information processing method according to claim 4,
wherein the outputting the progress information comprises:
calculating a rate of the reaction based on a difference between the start time and the end time and outputting the progress information including the calculated rate of the reaction.

7. The information processing method according to claim 1,
wherein the simulation is a molecular dynamics simulation, and
wherein the outputting the progress information comprises:
outputting a radial distribution function of at least one atom included in the interfacial model during execution of the simulation, the radial distribution function serving as characteristic information that is included in the progress information and that indicates a characteristic of a structure generated by the reaction.

8. The information processing method according to claim 7,
wherein the outputting the progress information comprises:
estimating that a time at which a predetermined peak included in the radial distribution function at a start time of the simulation disappears is an end time of the reaction, and outputting the progress information including the estimated end time of the reaction.

9. The information processing method according to claim 8,
wherein the outputting the progress information comprises:
calculating a volume of a reaction product, produced by the reaction, based on a coordination number of an atom included in the interfacial model with respect to a predetermined crystal axis, and outputting the progress information including the calculated volume of the reaction product.

10. The information processing method according to claim 9,
wherein the outputting the progress information comprises:
calculating a reaction time, indicating a time from when the reaction starts to when the reaction ends, based on a difference between the start time and the end time; and
calculating a rate of the reaction based on the calculated reaction time and the calculated volume of the reaction product and outputting the progress information including the calculated rate of the reaction.

11. The information processing method according to claim 1,
wherein the executing the simulation comprises:
executing a structural relaxation calculation on the interfacial model based on the acquired interfacial model information; and
executing the simulation on the interfacial model after the structural relaxation calculation.

12. An information processing system comprising:
a display controller that causes a display to display a second image after a first image is displayed on the display, the first image receiving an input of first solid material information indicating a first solid material and an input of second solid material information indicating a second solid material, the second image indicating progress information that indicates a degree of progress of a reaction between the first solid material and the second solid material and that is generated based on the first solid material information and the second solid material information that are input.

13. The information processing system according to claim 12,
wherein the display controller causes the display to further display a third image indicating first interfacial model information generated based on the first solid material information and the second solid material information that are input, and
wherein the first interfacial model information indicates a first interfacial model generated as a result of the first solid material and the second solid material coming into contact with each other, the first solid material having a first structure including first atoms, the second solid material having a second structure including second atoms, the first interfacial model including a boundary region between the first structure and the second structure.

14. The information processing system according to claim 13,
wherein the display controller causes the display to further display a fourth image and a fifth image, the fourth image receiving an input of calculation method information indicating a calculation method executable on the first interfacial model, the fifth image indicating second interfacial model information generated based on the calculation method information that is input.

15. A non-transitory computer-readable recording medium storing a program causing a computer to execute a process, the process comprising:
acquiring interfacial model information indicating an interfacial model of two or more solid materials;
executing a simulation of a reaction between the two or more solid materials based on the acquired interfacial model information; and
outputting progress information indicating a degree of progress of the reaction based on reaction information related to the reaction obtained by the simulation,
wherein the two or more solid materials each include atoms.
